(19) United States
(12) Patent Application Publication
(10) Pub. No.: US 2014/0230728 A1
(43) Pub. Date: Aug. 21, 2014

(54) VACUUM PROCESSING APPARATUS

(71) Applicant: Canon Anelva Corporation, Kawasaki-shi (JP)

(72) Inventors: Yuji Kajihara, Fuchu-shi (JP); Shogo Hiramatsu, Kawasaki-shi (JP); Kazuto Yamanaka, Sagamihara-shi (JP); Takashi Ueda, Chofu-shi (JP); Kazutoshi Yoshibayashi, Kawasaki-shi (JP); Kenji Sato, Koganei-shi (JP); Hajime Sahase, Fuchu-shi (JP); Hirohisa Hirayanagi, Atsugi-shi (JP); Masahiro Atsumi, Fuchu-shi (JP)

(73) Assignee: CANON ANELVA CORPORATION, Kawasaki-shi (JP)

(21) Appl. No.: 14/263,696

(22) Filed: Apr. 28, 2014

Related U.S. Application Data
(63) Continuation of application No. PCT/JP2012/005836, filed on Sep. 13, 2012.

(30) Foreign Application Priority Data
Oct. 28, 2011 (JP) 2011-236597

(51) Int. Cl. C23C 16/458

(52) U.S. Cl. CPC C23C 16/4582
USPC 118/719

(57) ABSTRACT

A vacuum processing apparatus includes a process chamber, a load lock chamber connected to the process chamber, and a transfer device configured to transfer a substrate from the load lock chamber to the process chamber. The transfer device is configured to move the substrate by gravity. The transfer device includes a guide configured to form a transfer path when the substrate moves by the gravity, and a stopper configured to limit movement of the substrate by the gravity when holding the substrate, and cancel the limitation when moving the substrate.

This application is a continuation of International Patent Application No. PCT/JP2012/005836 filed on Sep. 13, 2012, and claims priority to Japanese Patent Application No. 2011-236597 filed on Oct. 28, 2011, the entire content of both of which is incorporated herein by reference.

### BACKGROUND OF THE INVENTION

1. Field of the Invention

The present invention relates to a vacuum processing apparatus suitable for vacuum processing of a sheet- or plate-shaped substrate.

2. Description of the Related Art

Conventionally, to deposit about one to three layers on a substrate, a deposition apparatus formed by connecting one load lock chamber LL to one process chamber PC is sometimes used (for example, see PTL 1).

In such a deposition apparatus formed from one process chamber PC and one load lock chamber LL, no deposition can be performed in the process chamber PC during substrate exchange in the load lock chamber LL. For this reason, there is a limit in improving the substantial capacity utilization ratio, and it is difficult to improve the productivity (throughput) of deposition processing.

In the deposition apparatus formed from one process chamber PC and one load lock chamber LL, a device that transfers a vacuum container with a substrate being held in a carrier is used in some cases. In this apparatus, substrate attachment/removal may be done in a state in which the carrier is extracted from the vacuum container. A lot of man-hours are necessary for the substrate attachment/removal operation, and the challenge is to improve the productivity.

To shorten the operation time in the load lock chamber LL, a method has been employed that arranges a load lock chamber LL on each of the upstream and downstream sides of a process chamber PC, and a substrate is passed in one direction (for example, see PTL 2).

For example, a technique disclosed in PTL 2 uses a vacuum processing apparatus in which a plurality of process chambers are disposed between a load chamber and an unload chamber. In this vacuum processing apparatus, since a substrate can be transferred while being held in a carrier, multilayered films can continuously be formed on the substrate.

### CITATION LIST

### Patent Literature

PTL 1: Japanese Patent Laid-Open No. 9-272979
PTL 2: Japanese Patent Laid-Open No. 7-243037

### SUMMARY OF INVENTION

### Technical Problem

In the technique of PTL 2, however, the mechanism that transfers the carrier (or holder) with a held substrate in the vacuum container is complex, and cost reduction of the deposition apparatus is difficult. In addition, when the number of layers to be stacked on the substrate is small, the operation time in the load chamber and the unload chamber becomes relatively long. To raise the operation ratio of the process chamber, an enormous number of carriers need to be prepared. For these reasons, cost reduction is difficult.

The present invention has been made in consideration of the above-described problems, and has as its object to provide a vacuum processing apparatus that can improve the productivity of deposition processing and also contributes to cost reduction.

### Solution to Problem

According to the present invention, there is provided a vacuum processing apparatus comprising a process chamber, a load lock chamber connected to the process chamber, and a transfer device configured to transfer a substrate from the load lock chamber to the process chamber, wherein the transfer device is configured to move the substrate by gravity, and the transfer device comprises a guide configured to form a transfer path when the substrate moves by the gravity, and a stopper configured to limit movement of the substrate by the gravity when holding the substrate, and cancel the limitation when moving the substrate.

### Advantageous Effects of Invention

It is possible to provide a vacuum processing apparatus capable of easily saving energy because a substrate is transferred using gravity. Since this vacuum processing apparatus transfers a substrate using a relatively simple arrangement, initial cost or running cost can be reduced.

Other features and advantages of the present invention will be apparent from the following descriptions taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a front view of a vacuum processing apparatus according to an embodiment of the present invention;

FIG. 2 is a sectional view taken along a line A-A in FIG. 1;

FIG. 3 is a schematic view of a transfer device according to the first embodiment of the present invention;

FIG. 4 is a schematic view of the transfer device according to the first embodiment of the present invention;

FIG. 5 is a sectional view taken along a line B-B in FIG. 4;

FIG. 6 is an enlarged schematic view of the transfer device according to the first embodiment of the present invention;

FIG. 7 is a schematic view of a stopper of a transfer device according to an embodiment of the present invention;

FIG. 8A is an explanatory view of the operation of the stopper according to the embodiment of the present invention;

FIG. 8B is an explanatory view of the operation of the stopper according to the embodiment of the present invention; and

FIG. 9 is a sectional of a vacuum processing apparatus according to another embodiment of the present invention.

### DESCRIPTION OF THE EMBODIMENTS

Embodiments of the present invention will now be described with reference to the accompanying drawings. It should be noted that members, arrangements, and the like to be described below are merely specific examples of the present invention and are not intended to limit the scope of the present invention, and various changes and modifications can be made within the spirit and scope of the present invention, as a matter of course. Note that some components are not illustrated to prevent the drawings from becoming complex.

In this specification, a CVD apparatus (vacuum processing apparatus 1 or 2) for depositing DLC (Diamond Like Carbon) will be exemplified as a vacuum processing apparatus. However, the present invention is not limited to this. The present invention is applicable to, for example, a sputtering apparatus, another PVD apparatus, another CVD apparatus, or the like. The present invention is also applicable to a processing apparatus other than a deposition apparatus, for example, a dry etching apparatus, an asking apparatus, an annealing apparatus, or the like.

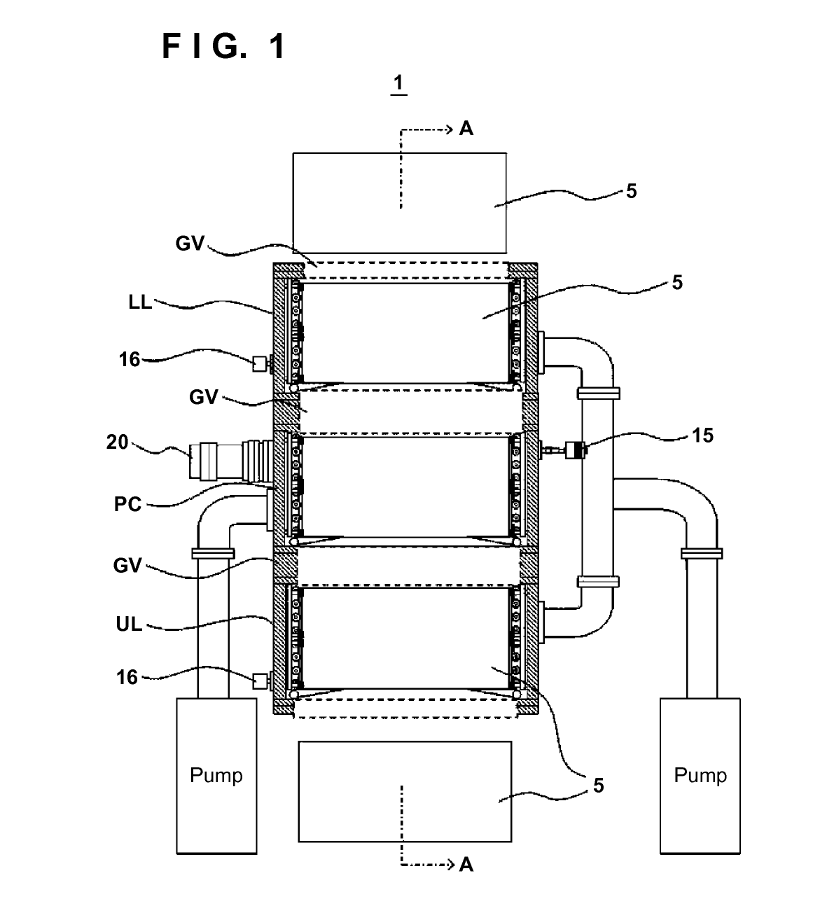

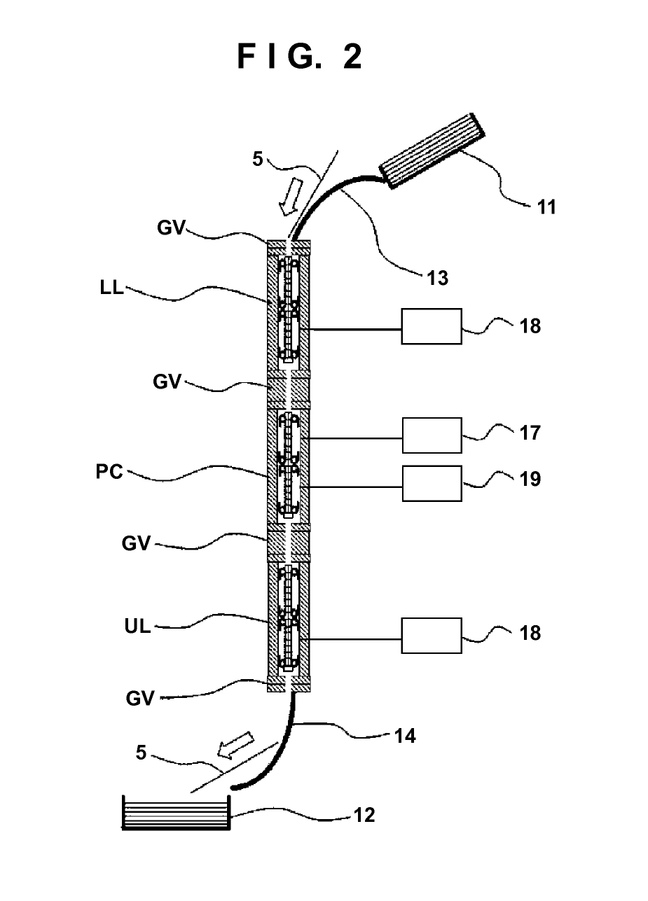

The schematic arrangement of the vacuum processing apparatus 1 will be described with reference to FIGS. 1 and 2. The vacuum processing apparatus 1 is a CVD apparatus in which three vacuum chambers are connected in series in the gravity direction. More specifically, in the vacuum processing apparatus 1, a load lock chamber LL, a process chamber PC, and an unload chamber UL are connected in line in this order via gate valves GV. Additionally, a magazine rack 11 that supplies an unprocessed substrate 5 to the load lock chamber LL and a collection case 12 that receives the processed substrate 5 discharged from the unload chamber UL are connected to the vacuum processing apparatus 1. The vacuum processing apparatus 1 includes a transfer device T that transfers the substrate 5 between the chambers, as will be described later. The process chamber PC receives the substrate 5 from the load lock chamber LL above, processes it, and discharges it to the unload chamber UL below.

The process chamber PC is a CVD deposition chamber configured to deposit DLC (Diamond Like Carbon), and includes a gas introduction system 17, a power supply system 19, and an exhaust system 20, although a detailed description thereof will be omitted. A gas introduced from the gas introduction system 17 is, for example, CxHy (hydrocarbon gas), H₂, N₂, or Ar. A vacuum gauge 15 configured to monitor the pressure during a process can also be provided on the process chamber PC. The process chamber PC includes an asking apparatus and a heater that heats the substrate 5 to a predetermined temperature in addition to the CVD processing apparatus for depositing a DLC film.

As the substrate 5, a conductive plate- or sheet-shaped substrate is usable. The substrate 5 can be, for example, a metal plate such as a stainless steel plate. If a process without bias application (to be described later) is, that is, a process without supplying power to the substrate is performed in the process chamber PC, the substrate 5 can be a nonconductive substrate.

The load lock chamber LL is a chamber that supplies the substrate 5 to the process chamber PC from above, and is connected to the upper side of the process chamber PC via the gate valve GV. The unload chamber UL is a chamber that discharges the substrate 5 from the process chamber PC to below, and is connected to the lower side of the process chamber PC via the gate valve GV. Each of these chambers includes a gas introduction system 18 and an exhaust system (not shown). The chambers are connected, via the gate valves GV, to the upper and lower sides of the process chamber PC where vacuum processing is performed.

When introducing the substrate 5 from the atmosphere side (magazine rack 11), a gas is introduced (vented) into the load lock chamber LL, and the gate valve GV is opened. After the substrate 5 is introduced, the gate valve GV is closed, and the load lock chamber LL is exhausted by a vacuum pump. Similarly, when introducing the substrate 5 from the process chamber PC, the unload chamber UL is exhausted by the vacuum pump, and the gate valve GV is opened in this state. After the substrate 5 is introduced, the gate valve GV is closed, and a gas is introduced (vented). After that, the substrate 5 is discharged to the atmosphere side (collection case). That is, each of the load lock chamber LL and the unload chamber UL has a mechanism for repetitively performing exhaust/vent and supplying/discharging the substrate 5. A vacuum gauge 16 configured to monitor the pressure in the chamber is attached to each of the load lock chamber LL and the unload chamber UL.

The magazine rack 11 is a device that supplies the substrate 5 one by one to the introduction port of the load lock chamber LL. In this embodiment, a device that feeds the substrates 5 stacked in the thickness direction to a slope 13 one by one is employed. The slope 13 guides the substrate 5 to the introduction port of the load lock chamber LL. Note that a robot having a hand capable of gripping the substrate 5 one by one may be used to directly supply the substrate 5 to the introduction port of the load lock chamber LL. The collection case 12 is a device that receives the substrate 5 discharged from the process chamber PC. A slope 14 is connected to the discharge port of the process chamber PC so that the substrate can be stacked in the thickness direction and collected one by one.

Both the magazine rack 11 and the collection case 12 may be replaced with conveyors such as belt conveyors. In this case, the unprocessed substrate 5 transported one by one from the preprocess by the conveyor can sequentially be supplied to the introduction port of the load lock chamber LL. In a similar manner, the processed substrate 5 can be transported one by one from the lower side of the unload chamber UL to the next process by the conveyor.

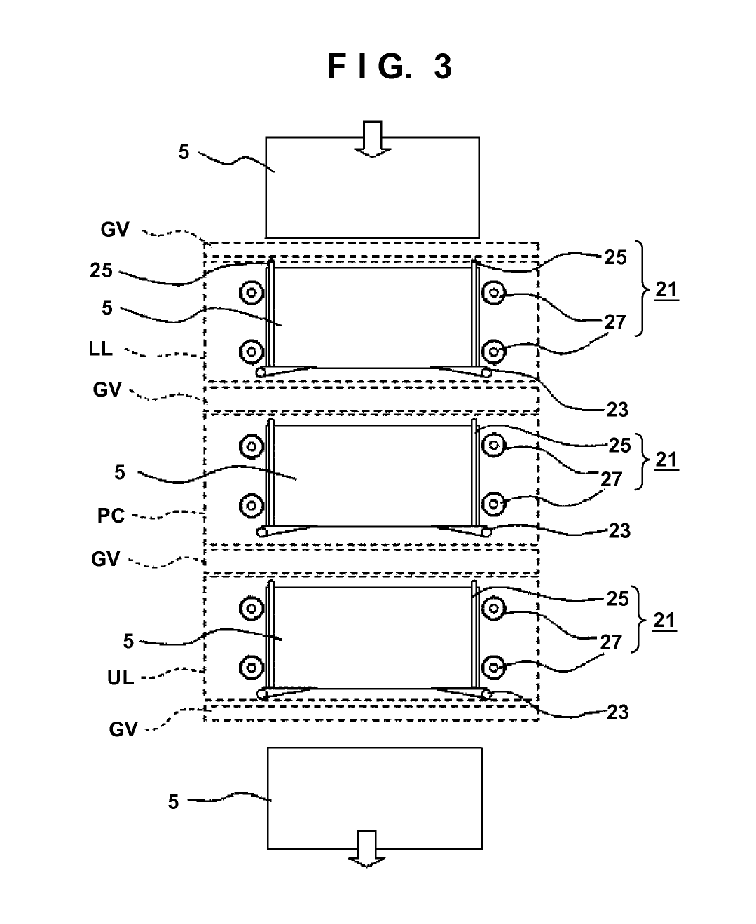

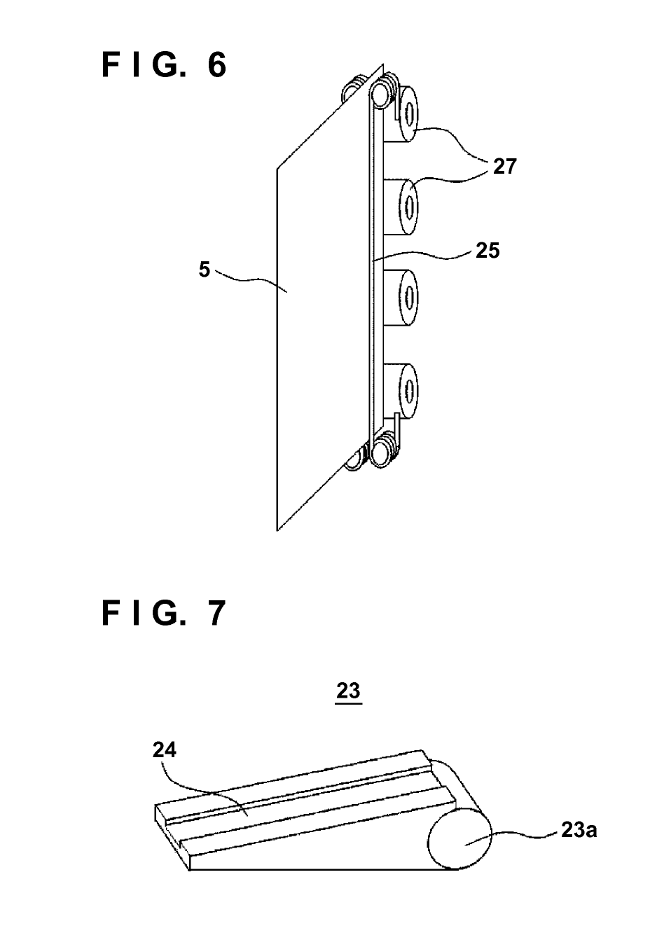

The transfer device for transferring a substrate will be described with reference to FIGS. 3 to 7. The transfer device T transfers a substrate using gravity. The transfer device T transfers the substrate 5 at predetermined timings through the load lock chamber LL, the process chamber PC, and the unload chamber UL in this order. The transfer device T includes guides 21 and stoppers 23. The guides 21 form a transfer path when the substrate 5 drops, and the operation of the stoppers 23 can determine the timing of supplying the substrate 5 to the next chamber located in the gravity direction.

As shown in FIG. 3, the guides 21 and the stoppers 23 are provided on the left and right sides in each chamber (both sides of the transfer path of the substrate 5) and limit the horizontal movement of the substrate 5 by a predetermined amount or more. Note that “drop” in this specification includes not only the movement in the gravity direction but also a moving direction of the substrate 5 that is transferred only by the effect of gravity. That is, when a transfer path having an angle with respect to the gravity direction is formed, the substrate 5 is transferred along the angle of the transfer path. This movement will also be referred to as “drop”.

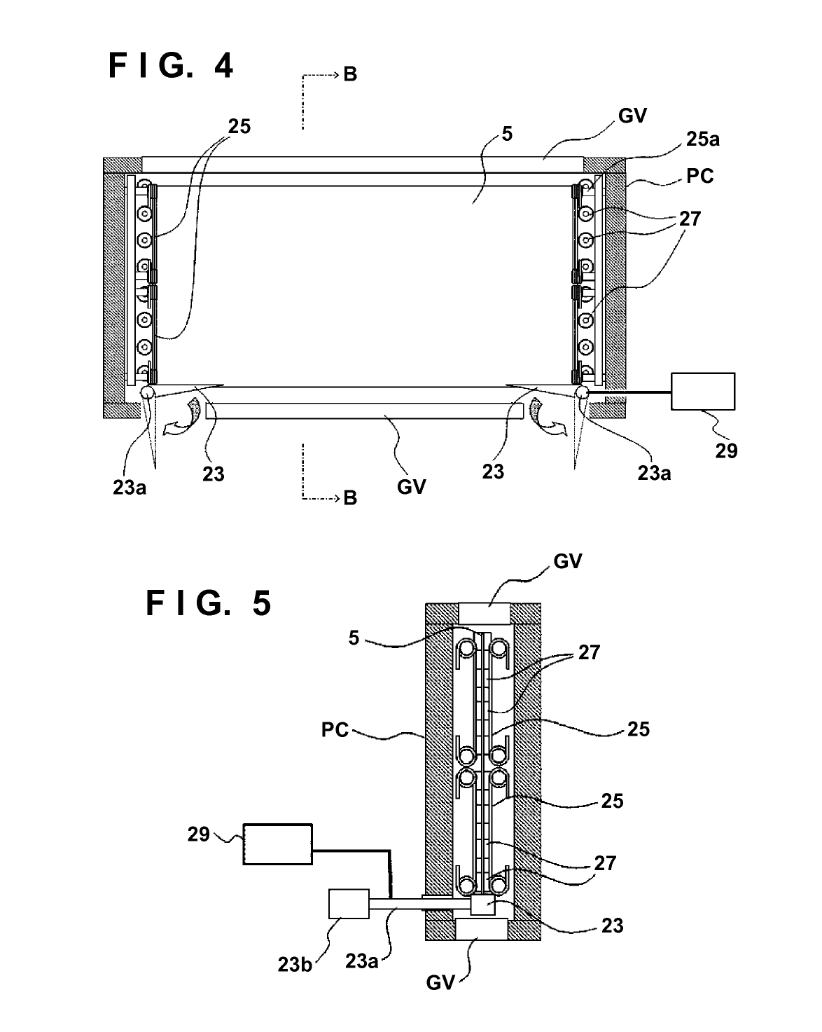

FIGS. 4 to 6 show the transfer device T in the process chamber PC. The guide 21 includes a wire 25 (first guide) that regulates the movement of the substrate 5 in the thickness direction and a roller 27 (second guide) that regulates the movement in the widthwise direction. A pair of wires 25 are provided on both surface sides of the substrate 5 in the thickness direction at a predetermined gap. A pair of rollers 27 are provided on both sides of the substrate 5 in the widthwise direction at a predetermined gap. That is, the guide 21 regulates the moving range of the substrate 5 in the horizontal direction (direction crossing the gravity direction) by the pair of wires 25 and the pair of rollers 27, thereby forming the transfer path of the substrate 5.

As shown in FIG. 4, the wire 25 of this embodiment is formed by fixing a thin line (wire) made of a metal between two projections 25a provided in the chamber. However, a plate-shaped member having smoothly processed corners, a roller, or a mesh may be used. Slits may be formed in the inner walls of the chamber located on both sides of the substrate 5 in the widthwise direction. The roller 27 is supported by a bearing. However, the substrate 5 may be brought into slidable contact with members having smoothly processed or coated surfaces.

The stopper 23 is a member capable of supporting or opening the lower side of the substrate 5 whose sides are supported by the guides 21. The stopper 23 can pivot about an shaft portion 23a at one end. When holding the substrate 5, the stopper 23 projects into the transfer path where the substrate 5 passes, thereby limiting the drop of the substrate 5 downward. On the other hand, when moving the substrate 5, the stopper 23 is retreated from the transfer path. Since this cancels the limitation of the drop of the substrate 5, the substrate 5 drops downward. The shaft portion 23a is connected to a driving device 23b (see FIG. 5) and can operate the stopper 23 at a predetermined timing. The stopper 23 of this embodiment is made of a refractory metal such as tungsten, and a bias power supply 29 can apply power (bias power) to it. For this reason, when the stopper 23 to which the power is applied abuts against the substrate 5, the bias power can be applied to the substrate 5.

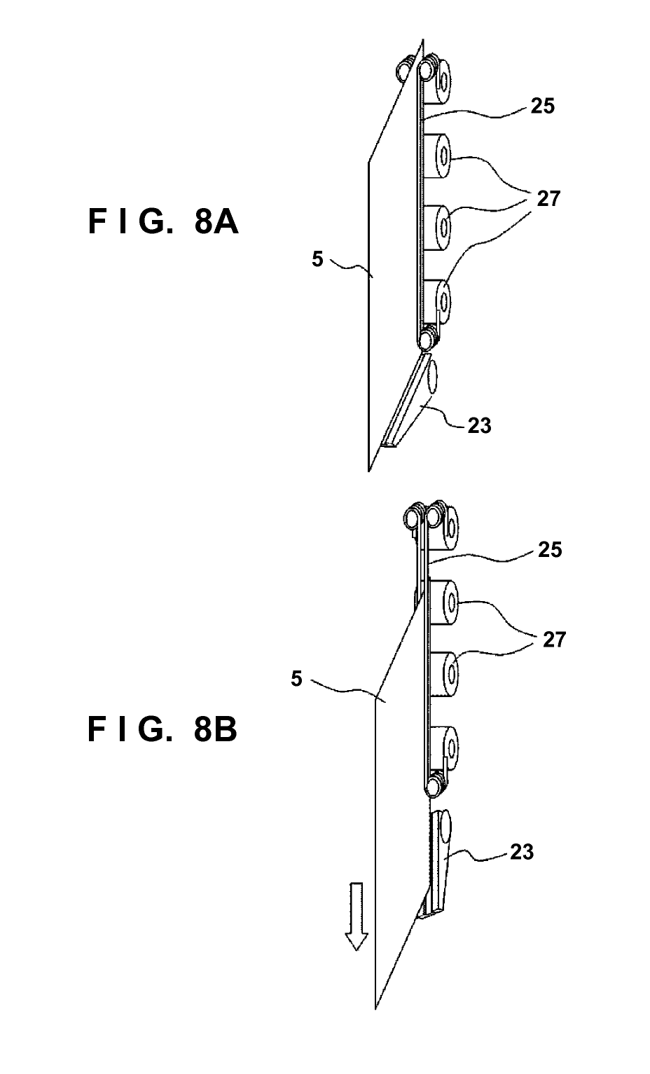

FIG. 7 is an enlarged view of the stopper 23. FIGS. 8A and 8B are explanatory views of the operation of the stopper 23. FIG. 8A shows a state in which the stopper 23 supports the lower side of the substrate 5, and FIG. 8B shows a state in which the stopper 23 pivots to transfer (drop) the substrate 5 to the lower side.

The stopper 23 has a slit 24 at a portion that abuts against the substrate 5. When supporting the lower side of the substrate 5, the slit 24 is fitted on the lower edge of the substrate 5 to regulate the position of the edge. For this reason, the support position of the substrate 5 in the transfer path can be adjusted. When the substrate 5 is supported at the central position of the opening of the gate valve GV, the substrate 5 can effectively be prevented from contacting the inner wall of the gate valve GV. In addition, the substrate 5 can smoothly be moved to the guides 21 in the next chamber.

When the stoppers 23 pivot to transfer the substrate 5 to the chamber located on the lower side, the slits 24 can be fitted on the edge of the substrate 5 in the widthwise direction to regulate the position of the edge. Hence, the support position of the substrate 5 during movement can be adjusted. When the support position of the substrate 5 during transfer is adjusted, the substrate 5 can be prevented from touching the inner wall of the gate valve GV. In addition, the substrate 5 can smoothly be moved to the guides 21 in the next chamber. Note that although the stopper 23 of this embodiment is configured to pivot about the shaft portion 23a, the stopper may move back and forth (slide) in a direction to project into the transfer path.

The processing step of the vacuum processing apparatus 1 will be described next. First, the gate valve GV (to be referred to as GV1) above the load lock chamber LL is opened. The substrate 5 held by the magazine rack 11 is supplied into the load lock chamber LL via the slope 13.

The gate valve GV1 is closed, and the load lock chamber LL is evacuated. At this time, the substrate 5 is supported by the guides 21 and the stoppers 23 (to be referred to as 231) in the load lock chamber LL. Next, the gate valve GV (to be referred to as GV2) between the load lock chamber LL and the process chamber PC is opened, and the stoppers 23 of the load lock chamber LL are operated to transfer the substrate 5 into the process chamber PC. The stoppers 231 are operated at the same time as the open of the gate valve GV2 or at a timing slightly later than the open of the gate valve GV2.

The substrate 5 is transferred to a predetermined position (through the transfer path) by the guides 21 in the process chamber PC and supported while abutting against the stoppers 23 (to be referred to as 232) in the process chamber PC. The gate valve GV2 is closed, and vacuum processing is performed in the process chamber PC. In this embodiment, hard carbon films (DLC films) are formed on both surfaces of the substrate 5 by a CVD process. During the vacuum processing, the substrate 5 is supported by the guides 21 and the stoppers 23 (232) in the process chamber PC. Additionally, bias power is applied to the substrate 5 via the stoppers 23 (232) in the process chamber PC.

When the vacuum processing has ended, the gate valve GV (to be referred to as GV3) between the process chamber PC and the unload chamber UL is opened, and the stoppers 23 (232) of the process chamber PC are operated to transfer the substrate 5 into the unload chamber UL. The substrate 5 is transferred to a predetermined position (transfer path) by the guides 21 in the unload chamber UL and supported while abutting against the stoppers 23 (to be referred to as 233) in the unload chamber UL.

The gate valve GV3 is closed, and nitrogen gas is introduced (vented) until the atmospheric pressure is obtained in the unload chamber UL. The gate valve GV (GV4) on the lower side of the unload chamber UL is opened, and the stoppers 23 (233) are operated to discharge the substrate 5 from the unload chamber UL. The discharged substrate 5 that has undergone the vacuum processing is collected by the collection case 12 via the slope 14. Note that the stoppers 232 and 233 are operated at the same time as the open of the gate valves GV (GV2 and GV3) interlocked with them or at a timing slightly later than their open.

The processing step of one substrate 5 has been described above. In the vacuum processing apparatus 1, during vacuum processing in the process chamber PC, evacuation or vent (open to atmosphere) can be performed in the load lock chamber LL and the unload chamber UL, and supply of the unprocessed substrate 5 or discharge or the processed substrate 5 can be done.

According to the vacuum processing apparatus 1 of this embodiment, the substrate 5 is transferred using gravity. For this reason, no power to drive the substrate 5 is necessary, and energy can easily be saved. Additionally, since the vacuum processing apparatus 1 uses neither a carrier nor a substrate holder, no particles are generated from the carrier or the like. Furthermore, since the vacuum processing apparatus transfers the substrate 5 using a simple arrangement, initial cost or running cost can be reduced.

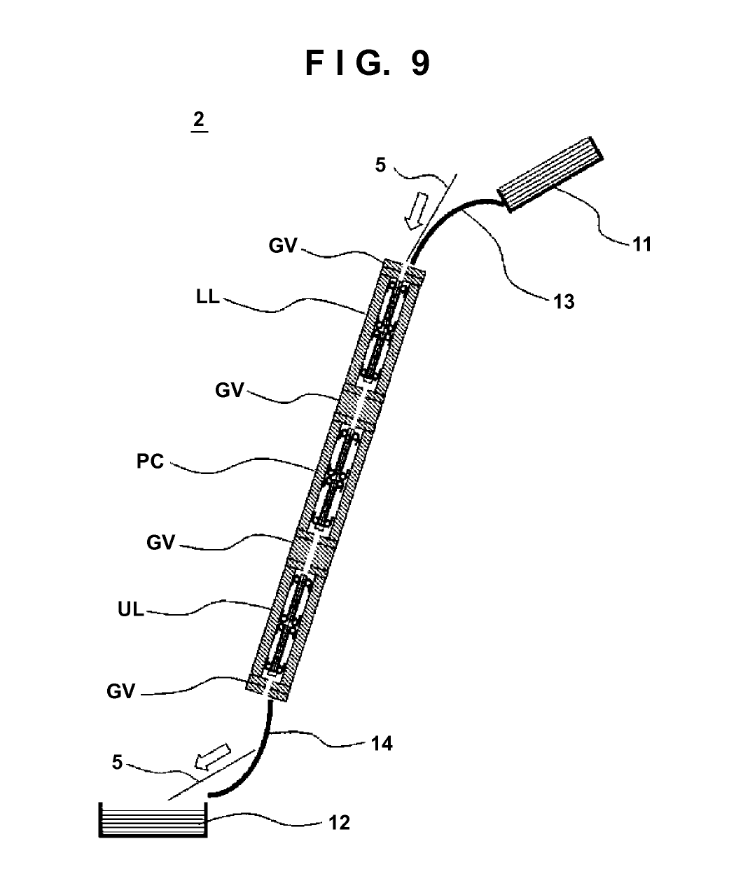

FIG. 9 shows a vacuum processing apparatus 2 according to another embodiment of the present invention. The same reference numerals denote the same members, arrangements, and the like as in the above-described embodiment, and a detailed description thereof will be omitted. The vacuum processing apparatus 2 is formed by connecting a load lock chamber LL, a process chamber PC, and an unload chamber UL at an angle with respect to the gravity direction. Since the transfer device of the vacuum processing apparatus 2 is formed at an angle with respect to the gravity direction, a substrate 5 is transferred through the chambers while being in contact with guides 21. For this reason, when the tilt angle of the vacuum processing apparatus 2 is adjusted, the position and speed of transfer of the substrate 5 can be adjusted. According to the vacuum processing apparatus 2, the position and speed of transfer of the substrate 5 can be adjusted in addition to the effects of the above-described vacuum processing apparatus 1.

Note that each of the vacuum processing apparatuses 1 and 2 according to the above-described embodiments includes the unload chamber UL. However, the present invention is also applicable to an arrangement that includes no unload chamber UL and directly discharges the processed substrate 5 from the process chamber PC, as a matter of course.

The present invention is not limited to the above embodiments and various changes and modifications can be made within the spirit and scope of the present invention. Therefore, to apprise the public of the scope of the present invention, the following claims are made.

### REFERENCE SIGNS LIST

LL . . . load lock chamber
PC . . . process chamber
GV . . . gate valve
T . . . transfer device
1, 2 . . . vacuum processing apparatus
5 . . . substrate
11 . . . magazine rack
12 . . . collection case
13, 14 . . . slope
15, 16 . . . vacuum gauge
17, 18 . . . gas introduction system
19 . . . power supply device
20 . . . exhaust system
21 . . . guide
23 . . . stopper
25 . . . wire
27 . . . roller

1. A vacuum processing apparatus, comprising:
a process chamber;
a load lock chamber connected to the process chamber; and
a transfer device configured to transfer a substrate from the load lock chamber to the process chamber,
wherein the transfer device is configured to move the substrate by gravity,
wherein the transfer device comprises:
a guide configured to form a transfer path when the substrate moves by the gravity; and
a stopper configured to limit movement of the substrate by the gravity when holding the substrate, and cancel the limitation when moving the substrate, and
wherein the guide includes:
a pair of first guides configured to guide two surfaces of the substrate, respectively, to regulate the movement of the substrate in a thickness direction; and
a pair of second guides configured to guide, out of four sides of the substrate, two sides along the transfer path so as to regulate the movement of the substrate in a widthwise direction, and
the pair of guides are formed by wires so as to guide the substrate in a state in which the two surfaces of the substrate are exposed.

2. The vacuum processing apparatus according to claim 1, wherein bias power can be applied to the substrate via the stopper in a state in which the stopper limits the movement of the substrate.

3. The vacuum processing apparatus according to claim 1, wherein the stopper has a slit configured to regulate a position of an edge of the substrate.

4. The vacuum processing apparatus according to claim 1, wherein the transfer path is configured to drop the substrate in a gravity direction.

5. The vacuum processing apparatus according to claim 1, wherein the transfer path is configured to drop the substrate at an angle with respect to a gravity direction.

6. The vacuum processing apparatus according to claim 1, wherein the stopper includes a member configured to pivot about a shaft portion parallel to a direction perpendicular to the two surfaces of the substrate.
